(19) United States
(12) Patent Application Publication
(10) Pub. No.: US 2006/0115674 A1
(43) Pub. Date: Jun. 1, 2006

(54) Organic electroluminescent device

(75) Inventors: Min-Ling Hung, Kanding Township (TW); Chung-Wen Ko, Sijhih City (TW); Tswen-Hsin Liu, Jhudong Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/074,036

(22) Filed: Mar. 7, 2005

(30) Foreign Application Priority Data
Nov. 26, 2004 (TW) 93136529

(51) Int. Cl. H01L 51/54; H05B 33/14

(52) U.S. Cl. 428/690; 428/917; 428/448; 313/504; 313/506; 257/102; 257/103; 257/E51.044

(57) ABSTRACT

An organic electroluminescent device comprising a light emitting layer including guest material and host material having formula (I):

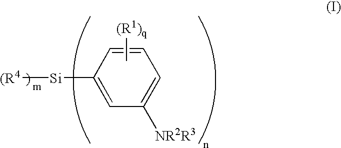

wherein R¹, R² and R³ individually represent H or substituent, R⁴ represents alkyl, alkenyl, heteroaryl, aryl group with or without substituent, q is an integer of 0 to 4, m is an integer of 1 to 3, n is an integer of 1 to 3, and m+n=4.

### BACKGROUND

The invention relates to an organic electroluminescent device (OLED), and more particularly to a host-guest type OLED.

OLED displays are among the most popular displays. FIG. 1 shows a conventional OLED. Substrate 8 is electrically insulated, comprising transparent glass or plastic materials. Anode 6 is disposed on substrate 8. Organic light emitting layer 4 is interposed between anode 6 and cathode 2. Anode 6 and cathode 2 are connected to external power supply 5. When the anode 6 bias exceeds cathode 2 bias, the diode is in forward bias, thus electrons and holes respectively from anode 6 and cathode 2 are injected into organic light emitting layer 4 to release light.

Phosphorescent efficiency is triple that of the fluorescent efficiency, making phosphorescent material an important OLED element.

A guest material can additionally be added to the light emitting layer to tune light color and luminescent efficiency.

A common host material used in OLEDs is 4,4′-N,N′-dicarbazole-biphenyl (CBP). However, electrons and holes have different transport speeds in CBP. This situation decreases OLED carrier recombination efficiency.

To resolve these and other problems, a better host material is desirable.

### SUMMARY

Accordingly, the invention provides an organic electroluminescent device.

An organic electroluminescent device comprises a light emitting layer including guest material and host material having formula (I): 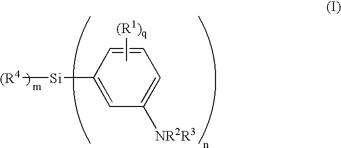
wherein R¹, R² and R³ individually represent H or a substituent, R⁴ represents alkyl, alkenyl, heteroaryl, aryl group with or without a substituent, q is an integer of 0 to 4, m is an integer of 1 to 3, n is an integer of 1 to 3, and m+n=4.

### DESCRIPTION OF THE DRAWINGS

The invention can be more fully understood by reading the subsequent detailed description and examples with references made to the accompanying drawings, wherein:

FIG. 1 is a cross section of a conventional OLED

FIG. 2 is a cross section an OLED of the embodiments;

FIG. 3 shows OLED luminescent efficiency of an example and a comparative example; and

FIG. 4 shows OLED lifetime of an example and a comparative example.

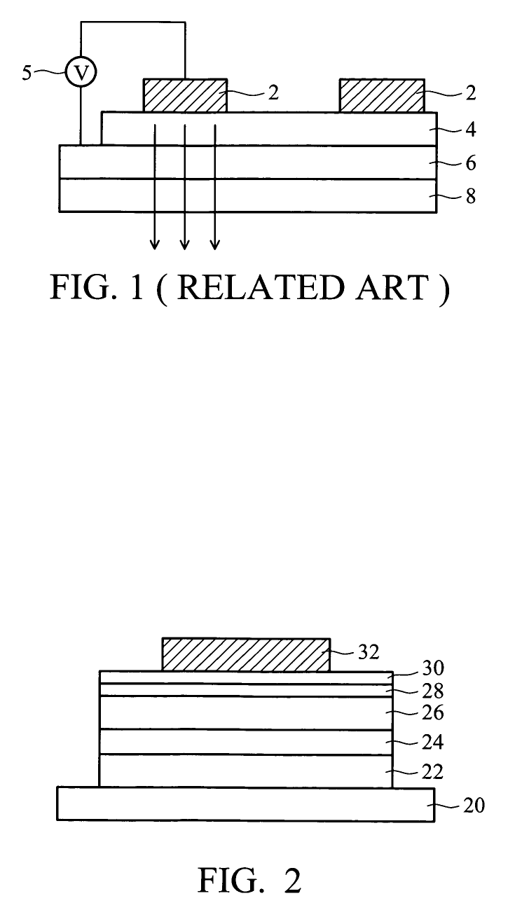

### DETAILED DESCRIPTION

The embodiments provide a host material having a silane compound represented by a following formula (I):

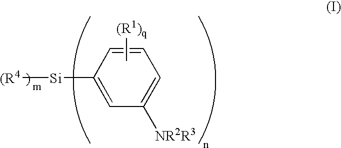

In formula (I), R¹, R² and R³ individually represent H or a substituent, comprising C₁-C₂₀ alkyl, such as methyl, ethyl, isopropyl, tert-butyl, n-octyl, n-decyl, n-hexadecyl, cyclopropryl, cyclopentyl or cyclohexyl groups; C₂-C₂₀ alkenyl; C₂-C₂₀ alkynyl, such as propargyl or 3-pentylnyl groups; C₁-C₂₀ heteroalkyl; C₃-C₄₀ aryl, such as phenyl, o-methylphenyl or naphthyl groups; C₃-C₄₀ heteroaryl, such as those containing one or more heteroatoms of oxygen, sulfur or nitrogen, with examples including imidazolyl, pyridyl, furyl, piperidyl, benzoxazolyl, thienyl, triazolyl or carbazolyl groups.

In formula (I), R⁴ represents C₁-C₂₀ alkyl, such as methyl, ethyl, isopropyl, n-octyl, n-decyl, n-hexadecyl, cyclopropryl, cyclopentyl or cyclohexyl groups; C₂-C₂₀ alkenyl, such as ethene, propylene, 2-octylene, 3-pentylene groups with or without substituent; C₁-C₅₀ heteroaryl, such as host containing one or more heteroatoms of oxygen, sulfur or nitrogen atoms, with examples including imidazolyl, pyridyl, furyl, piperidyl, benzoxazolyl, thienyl or triazolyl groups; C₆-C₃₀ aryl, such as phenyl, p-methylphenyl or naphthyl groups.

In formula (I), q is an integer of 0 to 4, m is an integer of 1 to 3, n is an integer of 1 to 3, and m+n=4.

Furthermore, R² and R³ may combine covalently to form heteroaryl group.

Examples of the host materials include:

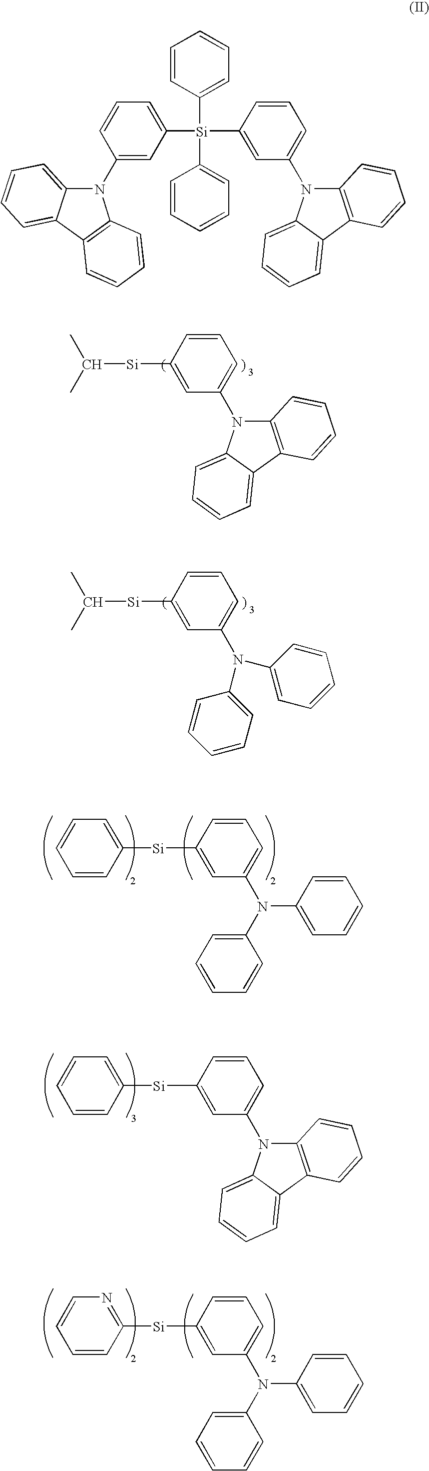

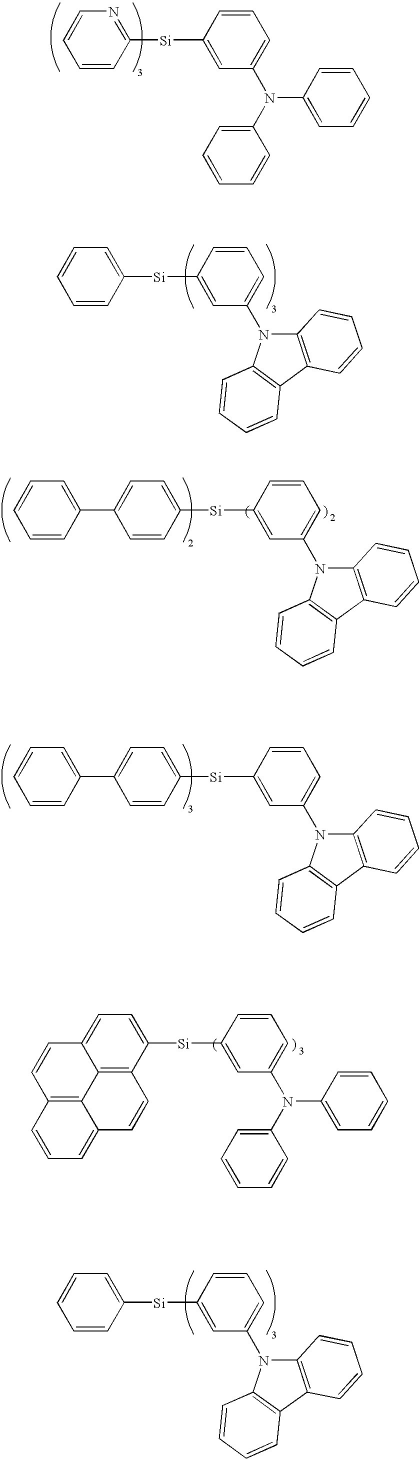

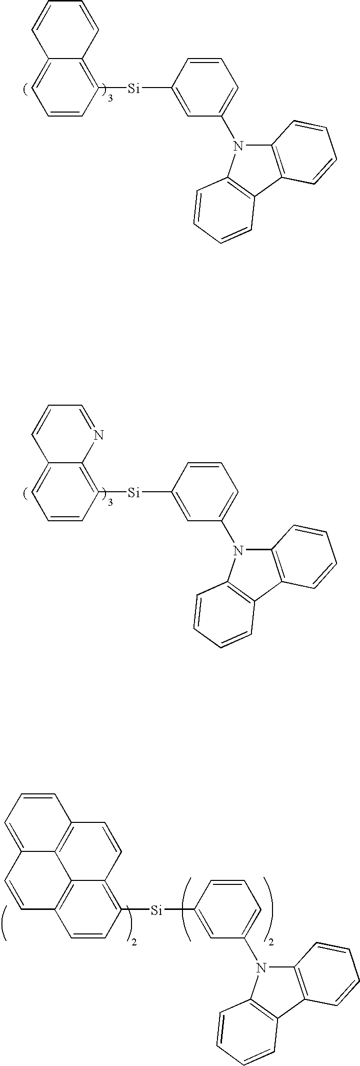

Light emitting layer 18 further comprises a guest material represented by the following formula (III) to emit red, green or blue light: 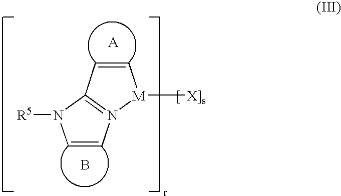
wherein M is a metal having an atomic weight more than 40, r is an integer at least 1, s is an integer at least 0, R⁵ represents H or C₁-C₂₀ alkyl, C₂-C₂₀ alkenyl, C₂-C₂₀ alkynyl, C₁-C₂₀ heteroalkyl, C₃-C₄₀ aryl, C₃-C₄₀ heteroaryl, X represents auxiliary ligand, A represents aryl or heteroaryl group, B represents aryl group.

Some guest materials used with the sliane compound of the invention for emitting red light include: 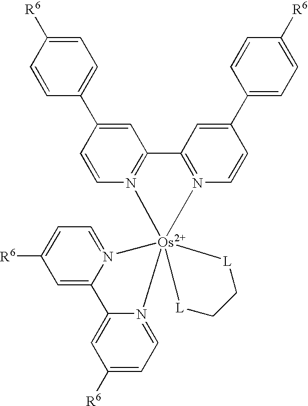
wherein R⁶ represents

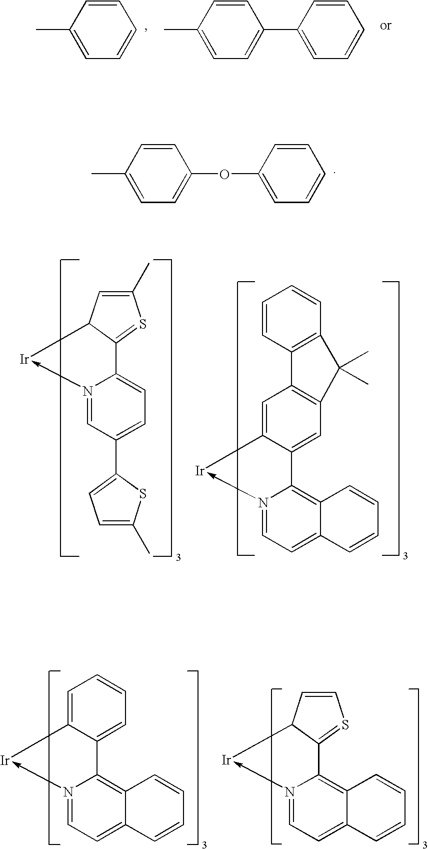

Some guest materials used with the sliane compound of the invention for emitting green light include:

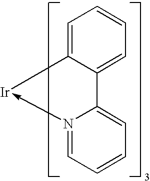

Some guest materials used with the sliane compound of the invention for emitting blue light include:

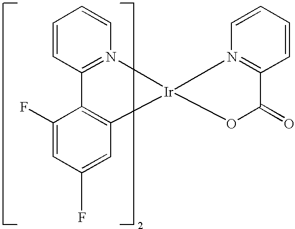

### Example

The compound (II) synthesis mechanism proceeds as follows:

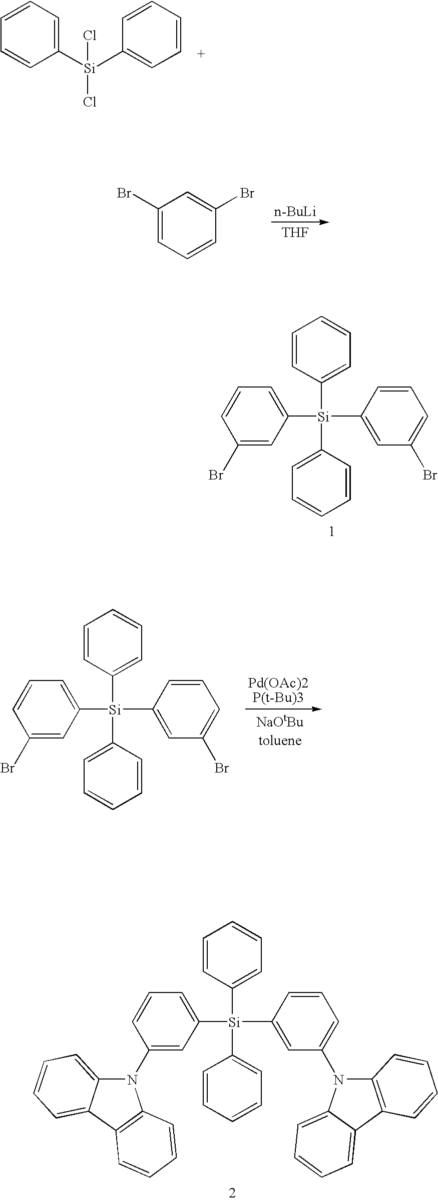

4.65 g 1,3-Dibromobenzene, 150 ml tetrahydrofurane and 8 ml n-Butyllithium were added to a flask at −78° C . 2 g dichlorodiphenylsilane was added to the flask in N₂ and stirred. 200 ml dichloromethane and 200 ml water were added to separate the organic layer. After concentration and purifyication, bis(3-bromo-phenyl)-diphenyl silane (compound 1) was obtained.

0.94 g carbazole, 0.59 g sodium t-butoxide, 0.12 g tri-t-butylphosphine, 0.034 g palladium acetate and 100 ml toluenewere added to a flask. 1.26 g compound 1 was added in the flask to N₂, stirred and refluxed. 200 ml dichloromethane and 200 ml water were added to separate the organic layer. After concentration and purifyication, compound 2 was obtained.

Referring to FIG. 2, 60˜80 nm hole injection layer 22, 20˜40 nm hole transport layer 24, 20˜40 nm compound (II) light emitting layer 26, 10˜25 nm hole blocking layer 28, 30˜35 nm electron transport layer 30 and cathode 32 were evaporated on the ITO substrate 20 sequentially to form an organic electroluminescent device. The organic light emitting layer 26 was co-doped with a guest material.

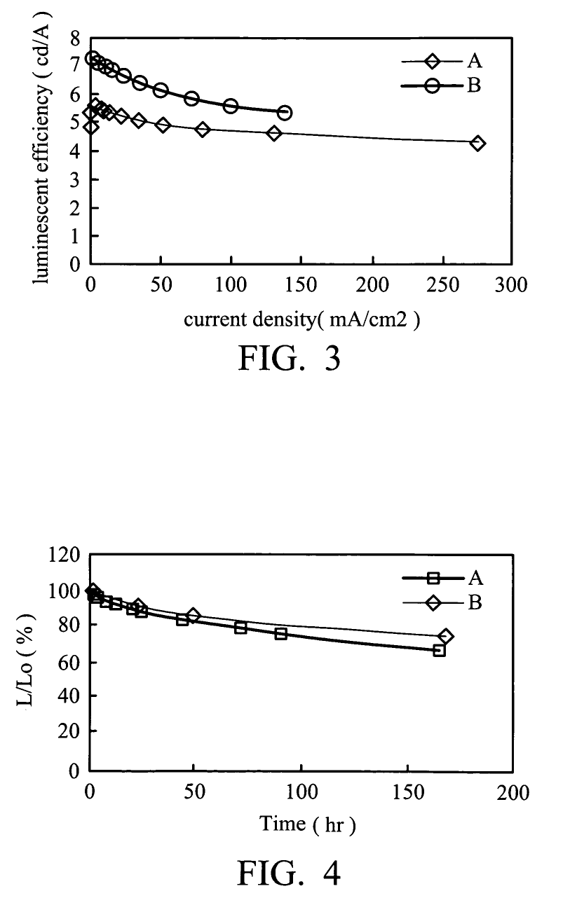

OLED luminescent efficiency reaches 7.3 cd/A, as shown in FIG. 3 line B, with lifetime of 166 hours of 20% decay, as shown in FIG. 4 line B.

### Comparative Example

Fabrication of this OLED is the same as the example, except for the CBP light emitting layer.

OLED luminescent efficiency reaches 5.5 cd/A, as shown in FIG. 3 line A, with lifetime is 162 hours of 30% decay, as shown in FIG. 4 line A.

Accordingly, the present invention OLED provides better luminescent efficiency and longer lifetime than conventional OLEDs.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. An organic electroluminescent device, comprising:
an anode and cathode pair; and
a light emitting layer interposed between the anode and cathode pair, wherein the light emitting layer comprises a host material and a guest material, wherein the host material comprises a silane compound respected by formula (I): 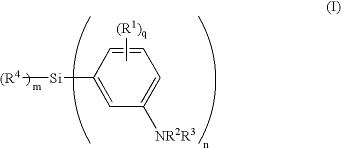
wherein R¹, R² and R³ individually represent H or a substituent; R⁴ represents alkyl, alkenyl, heteroaryl, or aryl group, each with or without substituent; q is an integer of 0 to 4, m is an integer of 1 to 3, n is an integer of 1 to 3, and m+n=4.

2. The organic electroluminescent device as claimed in claim 1, wherein the R² and R³ combine covalently to form heteroaryl.

3. The organic electroluminescent device as claimed in claim 1, wherein the silane compound comprises formula (II):

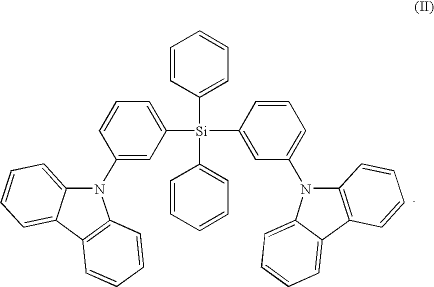

4. The organic electroluminescent device as claimed in claim 1, comprising:
a hole injection layer between the light emitting layer and the anode;
a hole transport layer between the hole injection layer and the light emitting layer;
a hole blocking layer between the light emitting layer and the cathode; and
an electron transport layer between the hole blocking layer and the cathode.

5. The organic electroluminescent device as claimed in claim 1, wherein the guest material comprises formula (III): 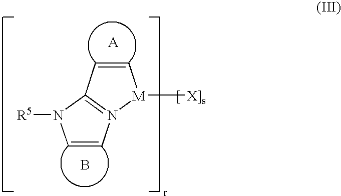
wherein M is a metal having an atomic weight exceeding 40; r is an integer at least 1; s is an integer at least 0; R⁵ represents H or substituent; X represents auxiliary ligand; A represents aryl or heteroaryl group; B represents aryl group.

6. The organic electroluminescent device as claimed in claim 5, wherein the guest material comprises formula: 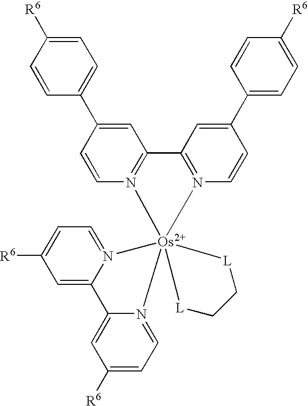
wherein R⁶ represents

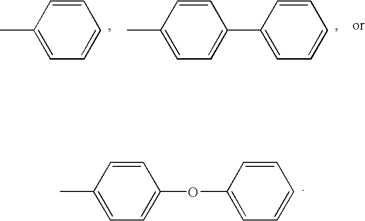

7. The organic electroluminescent device as claimed in claim 5, wherein the guest material comprises formula: [chemical structure]
